(19) United States
(12) Patent Application Publication
(10) Pub. No.: US 2020/0199776 A1
(43) Pub. Date: Jun. 25, 2020

(54) METHOD FOR PRODUCING SILICON SINGLE CRYSTAL

(71) Applicant: SUMCO CORPORATION, Tokyo (JP)

(72) Inventors: Masao SAITOU, Tokyo (JP); Kazuyuki EGASHIRA, Tokyo (JP)

(73) Assignee: SUMCO CORPORATION, Tokyo (JP)

(21) Appl. No.: 16/613,290

(22) PCT Filed: Apr. 5, 2018
(86) PCT No.: PCT/JP2018/014519

§ 371 Date: Nov. 13, 2019

(30) Foreign Application Priority Data
May 26, 2017 (JP) 2017-104172

(51) Int. Cl. C30B 15/20; C30B 29/06

(52) U.S. Cl. CPC C30B 15/20; C30B 29/06

(57) ABSTRACT

A production method of a monocrystalline silicon includes: growing the monocrystalline silicon pulled up from a silicon melt by the Czochralski process; and maintaining a pulling speed of the monocrystalline silicon when dislocations occur during pulling up of the monocrystalline silicon, so that the pulling up of the monocrystalline silicon is continued until a start point of the dislocations passes a temperature zone in which nuclei of oxygen precipitates form.

### TECHNICAL FIELD

The present invention relates to a production method of monocrystalline silicon.

### BACKGROUND ART

Oxygen precipitation nuclei in monocrystalline silicon grow, for instance, by heating (e.g., oxidative heating) in a device producing process to form bulk micro defects (BMD).

When the BMD are present on a top layer of a wafer for forming a semiconductor device, the BMD significantly influence properties of the semiconductor device. For instance, the BMD cause an increase in a leak current and a reduction in insulation properties of an oxidative film.

In contrast, the BMD formed inside the wafer form a gettering site for capturing contaminated impurities (e.g., metal impurities) and removing the contaminated impurities from the top layer of the wafer. Since an apparatus that is likely to cause metal contamination is sometimes used at, for instance, a dry etching step in the device producing process, it is extremely important for the wafer to have an excellent gettering ability.

Accordingly, when pulling up monocrystalline silicon by the Czochralski process, it is desired that oxygen precipitation nuclei form at a certain density in the monocrystalline silicon.

In the course of pulling up the monocrystalline silicon by the Czochralski process, dislocations sometimes occur in a straight body of the monocrystalline silicon. It has been known that, once dislocations occur, dislocations extend over a dislocation-free portion of the straight body.

Accordingly, Patent Literature 1 discloses that, when dislocations occur at a growth step of the straight body of the monocrystalline silicon, an output power of a heater is increased and/or a pulling speed of the monocrystalline silicon is sequentially increased, thereby immediately proceeding to formation of a tail to form a short tail and removing the monocrystalline silicon.

### CITATION LIST

### Patent Literatures

Patent Literature 1 JP 2009-256156 A

### SUMMARY OF THE INVENTION

### Problem(s) to be Solved by the Invention

However, in Patent Literature 1, since the output power of the heater is increased and/or the pulling speed is increased, thermal hysteresis of normal dislocation-free polycrystalline silicon at the straight body is changed to reduce the density of the oxygen precipitation nuclei in the monocrystalline silicon.

An object of the invention is to provide a monocrystalline silicon production method of avoiding reduction in oxygen precipitation nuclei in monocrystalline silicon.

### Means for Solving the Problem(s)

According to an aspect of the invention, a production method of a monocrystalline silicon, includes: growing the monocrystalline silicon pulled up from a silicon melt by Czochralski process; and maintaining a pulling speed of the monocrystalline silicon when dislocations occur during pulling up of the monocrystalline silicon so that the pulling up of the monocrystalline silicon is continued until a start point of the dislocations passes a temperature zone in which nuclei of oxygen precipitates form.

In the above aspect of the invention, the temperature zone in which nuclei of oxygen precipitates form is supposed to be in a range from 600 degrees C. to 800 degrees C.

In the above aspect of the invention, even after occurrence of dislocations, the pulling up of the monocrystalline silicon is continued at a constant pulling speed until the start point of the dislocations passes the temperature zone in which nuclei of oxygen precipitates form (hereinafter, also referred to as the “oxygen precipitation nucleation formation temperature zone”).

Accordingly, the monocrystalline silicon can be pulled up without changing thermal hysteresis of the normal monocrystalline silicon before occurrence of dislocations, so that the oxygen precipitation nucleus density in the monocrystalline silicon is not reduced. Particularly, since the temperature ranging from 600 degrees C. to 800 degrees C. is the temperature zone in which the oxygen precipitation nuclei form, the oxygen precipitation nucleus density is not reduced.

In this arrangement, the pulling speed of the monocrystalline silicon is preferably maintained in a temperature zone ranging from 400 degrees C. to 600 degrees C.

With this arrangement, since the temperature zone ranging from 400 degrees C. to 600 degrees C. is a temperature zone in which the formed oxygen precipitation nuclei grow, the oxygen precipitation nucleus density is not reduced.

In this arrangement, it is preferable that the monocrystalline silicon is used for a silicon wafer having a 300-mm diameter, and the temperature zone in which nuclei of oxygen precipitates form is present in a range from 597 mm to 1160 mm from a liquid surface of the silicon melt.

When pulling up the monocrystalline silicon for the silicon wafer having the 300-mm diameter, the range from 597 mm to 1160 mm above from the liquid surface of the silicon melt falls within the temperature zone ranging from 400 degrees C. to 800 degrees C. Accordingly, the oxygen precipitation nucleus density is not reduced since the pulling speed of the monocrystalline silicon is constant in the above range.

### BRIEF DESCRIPTION OF DRAWING(S)

FIG. 1 schematically illustrates a structure of a pull-up apparatus of monocrystalline silicon according to an exemplary embodiment of the invention.

FIG. 2 schematically illustrates the monocrystalline silicon pulled up without being removed after occurrence of dislocations in the exemplary embodiment.

FIG. 3 schematically illustrates the monocrystalline silicon removed after occurrence of dislocations and pulled up in the exemplary embodiment.

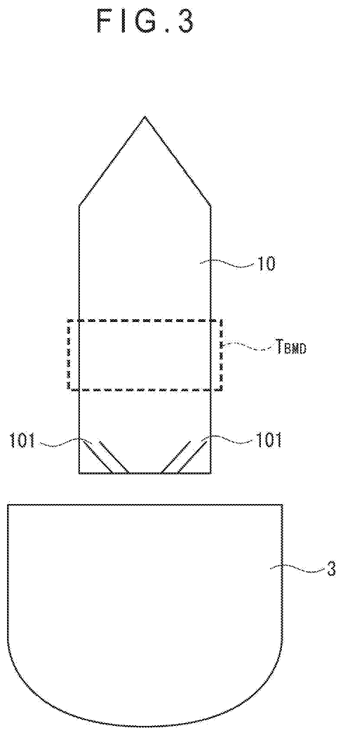

FIG. 4 is a graph for explaining a temperature zone ranging from 400 degrees C. to 600 degrees C. in the exemplary embodiment.

FIG. 5 is another graph for explaining a temperature zone ranging from 400 degrees C. to 600 degrees C. in the exemplary embodiment.

FIG. 6 is a graph showing a difference in a BMD density depending on a residence time in the temperature zone ranging from 400 degrees C. to 600 degrees C. in the exemplary embodiment.

FIG. 7 is a graph for explaining the residence time in the temperature zone ranging from 600 degrees C. to 800 degrees C. in Example of the invention and Conventional Example.

FIG. 8 is a graph showing a BMD density depending on a solidification rate in each of Example of the invention and Conventional Example.

### DESCRIPTION OF EMBODIMENT(S)

[1] Arrangement of Pull-Up Apparatus 1 of Monocrystalline Silicon

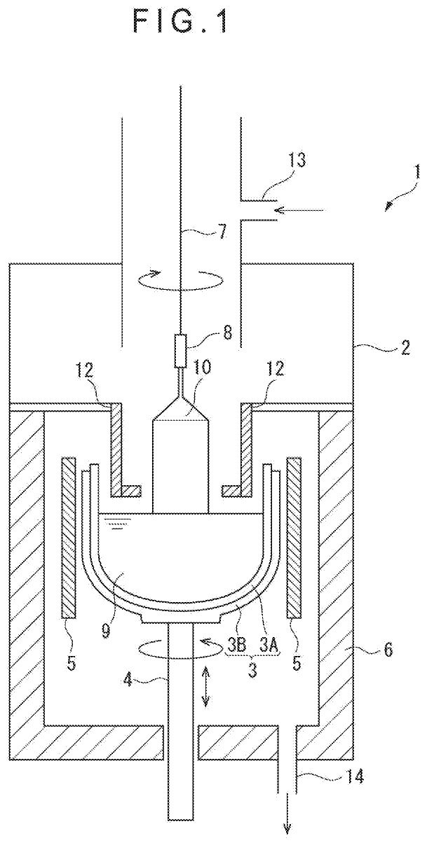

FIG. 1 schematically shows an exemplary structure of a pull-up apparatus 1 for monocrystalline silicon. A production method of monocrystalline silicon according to an exemplary embodiment of the invention is applicable to the pull-up apparatus 1. The pull-up apparatus 1, which pulls up monocrystalline silicon 10 according to the Czochralski process, includes a chamber 2 forming an external body and a crucible 3 disposed at the center of the chamber 2.

The crucible 3, which has a double structure formed by an inner quartz crucible 3A and an outer graphite crucible 3B, is fixed to an upper end of a support shaft 4 that is rotatable and vertically movable.

A resistance heater 5 is provided to an exterior of the crucible 3 in a manner to surround the crucible 3. A heat insulation material 6 is provided outside of the heater 5 and along an inner surface of the chamber 2.

A pulling shaft 7 (e.g., wire), which is rotatable at a predetermined speed coaxially with the support shaft 4 and in a direction opposite from or the same as the direction of the support shaft 4, is provided above the crucible 3. A seed crystal 8 is attached to a lower end of the pulling shaft 7.

A cylindrical heat shield 12 is disposed in the chamber 2.

The heat shield 12 shields the monocrystalline silicon 10 during the growth from high-temperature radiation heat from the silicon melt 9 in the crucible 3, the heater 5, and a side wall of the crucible 3. Near a solid-liquid interface (crystal growth interface), the heat shield plate 12 also prevents heat diffusion to the outside and controls the temperature gradient of the central portion of the monocrystalline silicon 10 and the peripheral portion of the monocrystalline silicon 10 in the direction of the pulling shaft.

The heat shield 12 also has a function as a regulation cylinder for exhausting evaporation from the silicon melt 9 to the outside of the furnace with use of inert gas introduced from a furnace top.

A gas inlet 13 for introducing inert gas (e.g. Ar gas) into the chamber 2 is provided at an upper part of the chamber 2. A gas outlet 14, through which the gas in the chamber 2 is sucked and discharged when a vacuum pump (not shown) is driven, is provided at a lower portion of the chamber 2.

The inert gas introduced from the gas inlet 13 into the chamber 2 flows down between the growing monocrystalline silicon 10 and the heat shield 12, flowing through a gap (liquid surface Gap) between the lower end of the heat shield 12 and the liquid surface of the silicon melt 9, subsequently, outside the heat shield 12, further outside the crucible 3, and subsequently flowing down outside the crucible 3 to be discharged from the exhaust outlet 14.

For the growth of the monocrystalline silicon 10 using the pull-up apparatus 1, while an inside of the chamber 2 is kept under an inert gas atmosphere and reduced pressure, a solid material (e.g., polycrystalline silicon) filled in the crucible 3 is heated by the heater 5 to be melted, thereby forming the silicon melt 9. After the silicon melt 9 is formed in the crucible 3, the pulling shaft 7 is lowered to soak the seed crystal 8 in the silicon melt 9. While the crucible 3 and the pulling shaft 7 are rotated in a predetermined direction, the pulling shaft 7 is gradually pulled up, thereby growing the monocrystalline silicon 10 overspreading the seed crystal 8.

[2] Production Method of Monocrystalline Silicon 10

Next, a production method of the monocrystalline silicon 10 according to the exemplary embodiment using the above pull-up apparatus 1 of the monocrystalline silicon will be described.

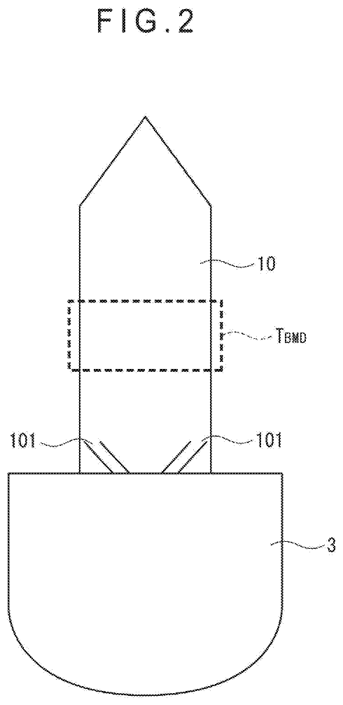

When dislocations occur during the pulling up of the monocrystalline silicon 10, the pulling up of the monocrystalline silicon 10 is continued without changing pull-up conditions (e.g., a pulling speed and a heating temperature by the heater 5) until a start point of dislocations (also referred to as a dislocation start point) 101 passes an oxygen precipitation nucleation formation temperature zone T_{BMD} as shown in FIG. 2.

The oxygen precipitation nucleation formation temperature zone T_{BMD} is a temperature zone ranging from 600 degrees C. to 800 degrees C. The pulling up of the monocrystalline silicon 10 is continued without changing the pull-up conditions until the dislocation start point 101 passes the temperature zone ranging from 600 degrees C. to 800 degrees C. With this operation, the thermal hysteresis of a portion, where no dislocations occur, of the monocrystalline silicon 10 becomes the same as thermal hysteresis of a usual dislocation-free monocrystalline silicon to be pulled up. Accordingly, a density of oxygen precipitation nuclei is not decreased at the portion of monocrystalline silicon 10 where no dislocations occur (hereinafter, also referred to as a dislocation-free portion).

If the monocrystalline silicon 10 is pulled up at an increased pulling speed after dislocations occur, a residence time of the portion, where no dislocations occur, of the monocrystalline silicon 10 in the temperature zone ranging from 600 degrees C. to 800 degrees C. would be shortened to change the thermal hysteresis. Accordingly, the density of the oxygen precipitation nuclei would be decreased at the portion of monocrystalline silicon 10 where no dislocations occur.

Though the pulling up of the monocrystalline silicon 10 may be continued without removing a portion lower than the dislocation start point 101 as shown in FIG. 2, the pulling up of the monocrystalline silicon 10 may be continued after removing the portion lower than the dislocation start point 101 from the monocrystalline silicon 10. The lower portion can be removed by increasing a heater power of the heater 5 and/or increasing the pulling speed of the monocrystalline silicon 10 within a range in which the density of the oxygen precipitation nuclei is not decreased.

In case of the monocrystalline silicon 10 (straight-body diameter from 301 mm to 320 mm) for a silicon wafer with a 300-mm diameter, a crystal temperature of the monocrystalline silicon 10 pulled up from a melt surface of the silicon melt 9 is determined depending on a distance from the melt surface of the silicon melt 9 as shown in Table 1. Accordingly, the thermal hysteresis of the monocrystalline silicon 10 is controllable by managing a height to which the monocrystalline silicon 10 is pulled up from the dislocation start point 101.

TABLE 1

| Crystal Temperature | Point from Melt |
|---|---|
| 800° C. | from 390 to 970 mm |
| 600° C. | from 597 to 1160 mm |
| 400° C. | from 796 to 1368 mm |

[3] Pulling Up of Monocrystalline Silicon 10 at Temperature From 400° C. to 600° C.

Next, the reason for pulling up of the monocrystalline silicon 10 without changing the pull-up conditions in the temperature zone from 400 degrees C. to 600 degrees C., which is below the oxygen precipitation nucleation formation temperature zone T_{BMD} will be described.

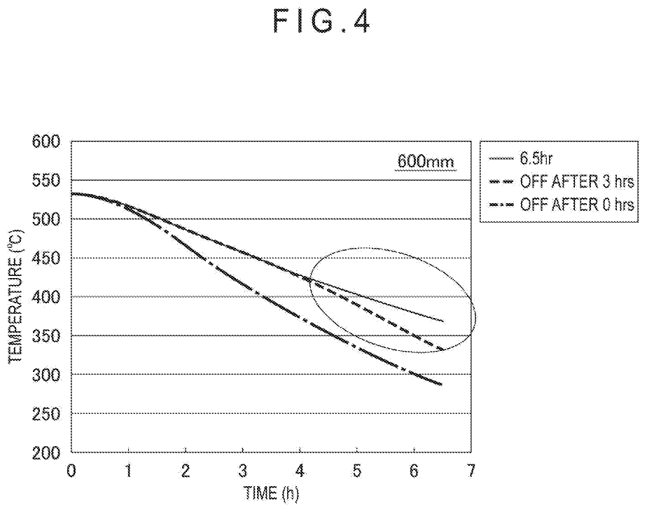

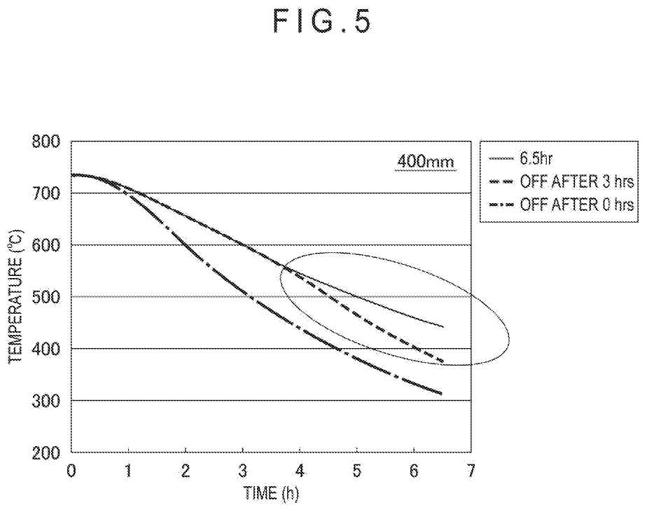

FIGS. 4 and 5 show crystal cooling curves respectively showing the measured temperatures of the monocrystalline silicon 10: when the monocrystalline silicon 10 was removed immediately after occurrence of dislocations and pulled up at the changed pulling speed; when the monocrystalline silicon 10 continued to be pulled up until the elapse of three hours after occurrence of dislocations, subsequently removed, and pulled up at the changed pulling speed; and when the monocrystalline silicon 10 continued to be pulled up for 6.5 hours after occurrence of dislocations without any change. FIG. 4 shows the crystal cooling curves at 600 mm from the liquid surface of the silicon melt 9. FIG. 5 shows the crystal cooling curves at 400 mm from the liquid surface of the silicon melt 9.

As seen from FIGS. 4 and 5, a residence time of a dislocation-free portion of the monocrystalline silicon 10 in the temperature zone ranging from 400 degrees C. to 600 degrees C. is longer when the monocrystalline silicon 10 continued to be pulled up for 6.5 hours without any change than when the monocrystalline silicon 10 was removed after the monocrystalline silicon 10 continued to be pulled up for three hours.

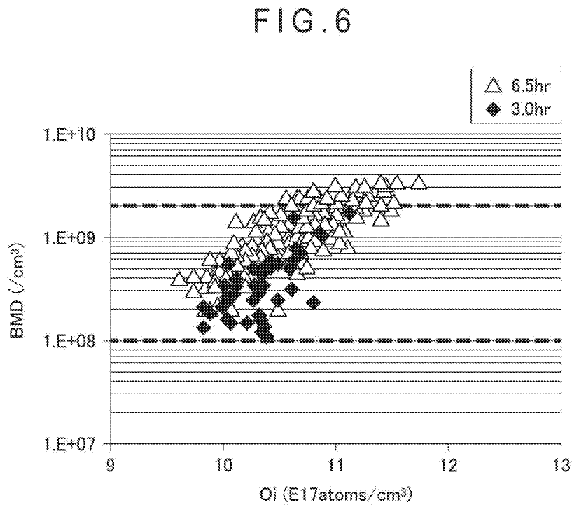

A relationship between the number of the oxygen precipitation nuclei and the BMD density was examined for each of when the monocrystalline silicon 10 was removed after the monocrystalline silicon 10 continued to be pulled up for three hours and when the monocrystalline silicon 10 continued to be pulled up without any change. As shown in FIG. 6, it was observed that the BMD density and the number of the oxygen precipitation nuclei were larger when the monocrystalline silicon 10 continued to be pulled up without any change.

It was found from the foregoing that, also in the temperature zone ranging from 400 degrees C. to 600 degrees C., the BMD density became large by pulling up the monocrystalline silicon 10 at the same pulling speed as that in the dislocation-free monocrystalline silicon 10. It is inferred that, when the oxygen precipitation nuclei formed in the temperature zone ranging from 600 degrees C. to 800 degrees C. have a sufficient residence time in the temperature zone ranging from 400 degrees C. to 600 degrees C., the oxygen precipitation nuclei grow to improve the BMD density.

Accordingly, it was confirmed that the BMD density in the monocrystalline silicon 10 was able to be improved by maintaining the pull-up conditions in the temperature zone ranging from 400 degrees C. to 600 degrees C. in addition to the pull-up conditions in the oxygen precipitation nucleation formation temperature zone T_{BMD}.

### EXAMPLES

Next, Examples of the invention will be described. However, the invention is by no means limited to Examples.

The monocrystalline silicon 10 with occurrence of dislocations during the pulling up was compared in terms of the change in the BMD density between Conventional Example where, after occurrence of dislocations, a residence time in the temperature zone ranging from 400 degrees C. to 800 degrees C. was shortened by increasing the pulling speed and Example where, after occurrence of dislocations, the residence time in the temperature zone ranging from 400 degrees C. to 800 degrees C. was prolonged by maintaining the pulling speed without change.

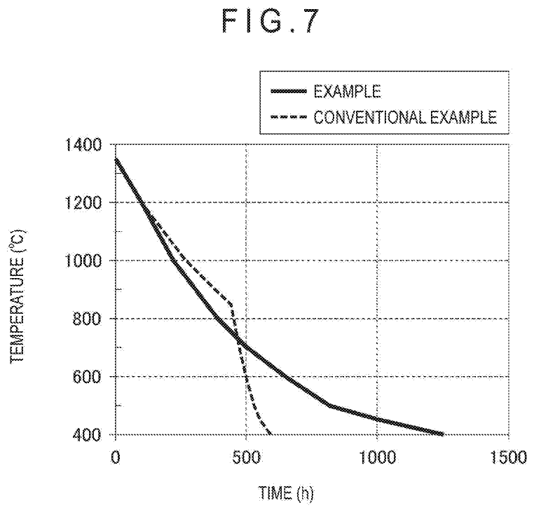

A difference in the residence time between Conventional Example and Example is shown in Table 2 and FIG. 7.

TABLE 2

| Example | | Conventional Example | |
|---|---|---|---|
| Time (min) | Temp. (° C.) | Time (min) | Temp. (° C.) |
| 0 | 1350 | 0 | 1350 |
| 100 | 1200 | 100 | 1200 |
| 220 | 1000 | 270 | 1000 |
| 390 | 800 | 380 | 900 |
| 500 | 700 | 440 | 850 |
| 650 | 600 | 450 | 800 |
| 820 | 500 | 470 | 700 |
| 1000 | 450 | 500 | 600 |
| 1250 | 400 | 530 | 500 |
| 1500 | 350 | 550 | 450 |
| — | — | 590 | 400 |
| — | — | 620 | 350 |

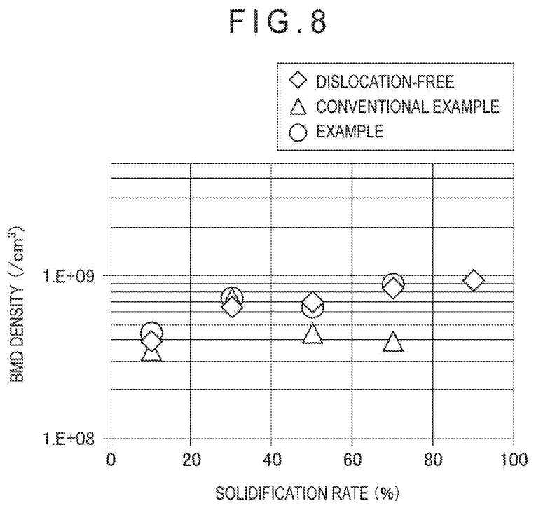

The monocrystalline silicon 10 in each of Example, Conventional Example, and the dislocation-free monocrystalline silicon 10 were pulled up along the whole length and measured in terms of the change in the BMD density depending on the solidification rate. Results are shown in FIG. 8.

As seen from FIG. 8, the BMD density is decreased at the solidification rate of 50% or more.

In contrast, it was observed in Example, where the monocrystalline silicon 10 even after occurrence of dislocations was pulled up at the same pulling speed as that before occurrence of dislocations, that the BMD density was kept at the same value as that in the dislocation-free monocrystalline silicon 10, thereby avoiding the decrease in the BMD density. In FIG. 8, the BMD density was not plotted at the solidification rate of 90% because dislocations occurred at a portion having the solidification rate of 80% or more, so that the BMD density was not able to be measured.

### EXPLANATION OF CODE(S)

1 . . . pulling-up apparatus, 2 . . . chamber, 3 . . . crucible, 3A . . . quartz crucible, 3B . . . graphite crucible, 4 . . . support shaft, 5 . . . heater, 6 . . . heat insulation material, 7 . . . pulling shaft, 8 . . . seed crystal, 9 . . . silicon melt, 10 . . . monocrystalline silicon, 12 . . . heat shield, 13 . . . gas inlet, 14 . . . exhaust outlet, 101 . . . dislocation start point.

1. A production method of a monocrystalline silicon, the method comprising: growing the monocrystalline silicon pulled up from a silicon melt by Czochralski process; and
maintaining a pulling speed of the monocrystalline silicon when dislocations occur during pulling up of the monocrystalline silicon so that the pulling up of the monocrystalline silicon is continued until a start point of the dislocations passes a temperature zone in which nuclei of oxygen precipitates form.

2. The production method of the monocrystalline silicon according to claim 1, wherein
the temperature zone in which nuclei of oxygen precipitates form ranges from 600 degrees C. to 800 degrees C.

3. The production method of the monocrystalline silicon according to claim 2, wherein
the pulling speed of the monocrystalline silicon is maintained in a temperature zone ranging from 400 degrees C. to 600 degrees C.

4. The production method of the monocrystalline silicon according to claim 1, wherein
the monocrystalline silicon is used for a silicon wafer having a 300-mm diameter, and
the temperature zone in which nuclei of oxygen precipitates form is present in a range from 597 mm to 1160 mm from a liquid surface of the silicon melt.
